(19) United States
(12) Patent Application Publication
(10) Pub. No.: US 2014/0230872 A1
(43) Pub. Date: Aug. 21, 2014

(54) THERMOELECTRIC GENERATOR

(71) Applicant: kELK ) KELK LTD., Hiratsuka-shi, Kanagawa (JP)

(72) Inventors: Kazuya Makino, Kanagawa (JP); Hiromasa Kaibe, Kanagawa (JP); Hirokuni Hachiuma, Kanagawa (JP)

(73) Assignee: KELK LTD., Hiratsuka-shi, Kanagawa (JP)

(21) Appl. No.: 14/346,651

(22) PCT Filed: Oct. 5, 2012
(86) PCT No.: PCT/JP2012/075937

§ 371 Date: Mar. 21, 2014

(30) Foreign Application Priority Data
Oct. 5, 2011 (JP) 2011-221378

(51) Int. Cl. H01L 35/32

(52) U.S. Cl. CPC H01L 35/32
USPC 136/205

(57) ABSTRACT

A thermoelectric generator includes: a heat-receiving plate being adapted to receive heat; a cooling plate being maintained at a low temperature as compared with the heat-receiving plate; a thermoelectric module being interposed between the heat-receiving plate and the cooling plate; a terminal block at which a lead wire from the thermoelectric module is connected to an external power line, the terminal block being located on the cooling plate; and a metal cover being fixed on the cooling plate to cover the terminal block.

### TECHNICAL FIELD

The present invention relates to a thermoelectric generator. In particular, the present invention relates to a thermoelectric generator that generates electricity using heat received from a heat source.

### BACKGROUND ART

There has been conventionally known a thermoelectric generator including a heat-receiving plate, a cooling plate, and a thermoelectric module being interposed between the heat-receiving plate and the cooling plate and including a number of thermoelectric generation elements, the thermoelectric generator generating electricity using the Seebeck effect caused in the thermoelectric module when the heat-receiving plate is exposed to, for instance, an exhaust gas from an engine (see, for instance, Patent Literature 1).

A plurality of the thermoelectric generators of the above type are installed to surround an exhaust pipe and an exhaust gas from the exhaust pipe is directed to the heat-receiving plate of each of the thermoelectric generators. A lead wire is pulled out from the thermoelectric module interposed between the heat-receiving plate and the cooling plate to obtain voltage.

### CITATION LIST

### Patent Literature(s)

Patent Literature 1: JP-A-2006-125341

### SUMMARY OF THE INVENTION

### Problem(s) to be Solved by the Invention

The lead wire pulled out from the thermoelectric module is affected by a radiant heat from the exhaust pipe heated by the exhaust gas, so that a coating and the like are likely to be melted. According to Patent Literature 1, the thermoelectric generator is covered by an annular member and the lead wire is pulled out of the annular member to be connected to a connector. However, in some device arrangements, resin members serving as a connector, a terminal block and the like are possibly located inside the annular member and thus may be damaged by the radiant heat from the exhaust pipe.

Incidentally, JP-A-61-132245 discloses a technique for protecting a terminal block from a radiant heat. According to the disclosed technique, the terminal block is covered by a water-cooling jacket to be cooled so that the terminal block is unaffected by a radiant heat from a heat source. However, employment of such a water-cooling jacket requires a circulation system for a cooling water, resulting in a disadvantageous large-scale arrangement.

An object of the invention is to provide a thermoelectric generator with a simple arrangement capable of reliably protecting a resin member in the vicinity of connections of lead wires from a radiant heat.

### Means for Solving the Problem(s)

According to a first aspect of the invention, a thermoelectric generator includes: a heat-receiving plate being adapted to receive heat; a cooling plate being maintained at a low temperature as compared with the heat-receiving plate; a thermoelectric module being interposed between the heat-receiving plate and the cooling plate; a terminal block at which a lead wire from the thermoelectric module is connected to an external power line, the terminal block being located on the cooling plate; and a metal cover being fixed on the cooling plate to cover the terminal block.

According to a second aspect of the invention, the cooling plate is provided with a through hole through which the lead wire is inserted, the through hole is covered by the terminal block, and an O-ring is interposed between the cooling plate and the terminal block to surround the through hole.

According to a third aspect of the invention, the terminal block includes a plurality of terminal blocks that are centralized in a vicinity of a center of the cooling plate.

According to a fourth aspect of the invention, the thermoelectric generator further includes: a thermoelectric generation unit including the heat-receiving plate, the cooling plate and the thermoelectric module; a metallic shielding cover being adapted to cover the thermoelectric generation unit; and a fixing bracket being adapted to fix the thermoelectric generator at a predetermined position, in which the terminal blocks each include: a resin spacer being located on the cooling plate; a metallic terminal being located on the spacer to connect the lead wire and the power line to each other; a resin cover being adapted to cover the spacer and the terminal; a first O-ring being interposed between the cooling plate and the spacer; a second O-ring being interposed between the spacer and the terminal; and a third O-ring being interposed between the spacer and the resin cover.

According to the first aspect of the invention, since the terminal block is covered by the metal cover, radiation of the heat received by the heat-receiving plate can be blocked by the metal cover. Further, since the metal cover is fixed to the cooling plate, the temperature of the metal cover is kept substantially as low as that of the cooling plate. Thus, the terminal block covered by the metal cover is efficiently protected from a radiant heat to suppress damage on the terminal block, especially a resin member thereof.

According to the second aspect of the invention, the O-ring made of a resin such as rubber is used in the terminal block and the influence of a radiant heat on the O-ring is reduced to prevent, for instance, deformation of the O-ring. Thus, airtightness can be favorably maintained to prevent water drop and steam from entering through the through hole.

According to the third aspect of the invention, since a plurality of terminal blocks are centralized near the center of the cooling plate with a distance between the periphery of the cooling plate and the terminal blocks being increased, thereby further reducing the influence of the radiant heat from the periphery of the cooling plate.

According to the fourth aspect of the invention, the shielding cover serves to prevent the cooling plate of the thermoelectric unit from being heated up. A radiant heat generated by the heated shielding cover at this time is blocked by the metal cover, so that the terminal block is unaffected. Thus, the spacer made of a resin and the resin cover are reliably protected and deformation of the first to third O-rings is prevented to reliably ensure airtightness.

### BRIEF DESCRIPTION OF DRAWING(S)

FIG. 1 schematically shows an example in which a thermoelectric generator according to an exemplary embodiment is provided at a burner-combustion portion in a heat-treating furnace.

FIG. 2 is a partially exploded perspective view showing the entirety of the thermoelectric generator.

FIG. 3 is a partially sectional perspective view showing the entirety of a thermoelectric generation unit of the thermoelectric generator.

FIG. 4 is a plan view of the thermoelectric generation unit.

FIG. 5 is a side view of the thermoelectric generation unit.

FIG. 6 is a sectional view taken along a line VI-VI in FIG. 4.

FIG. 7 is a back view of a cooling plate.

FIG. 8A is a plan view showing a support structure of a thermoelectric module.

FIG. 8B is a sectional view showing a relevant part of the thermoelectric module.

FIG. 9 is a sectional view showing the vicinity of a terminal block of the thermoelectric generation unit.

FIG. 10 is an exploded perspective view showing the vicinity of the terminal block.

### DESCRIPTION OF EMBODIMENT(S)

An exemplary embodiment of the invention will be described below with reference to the attached drawings.

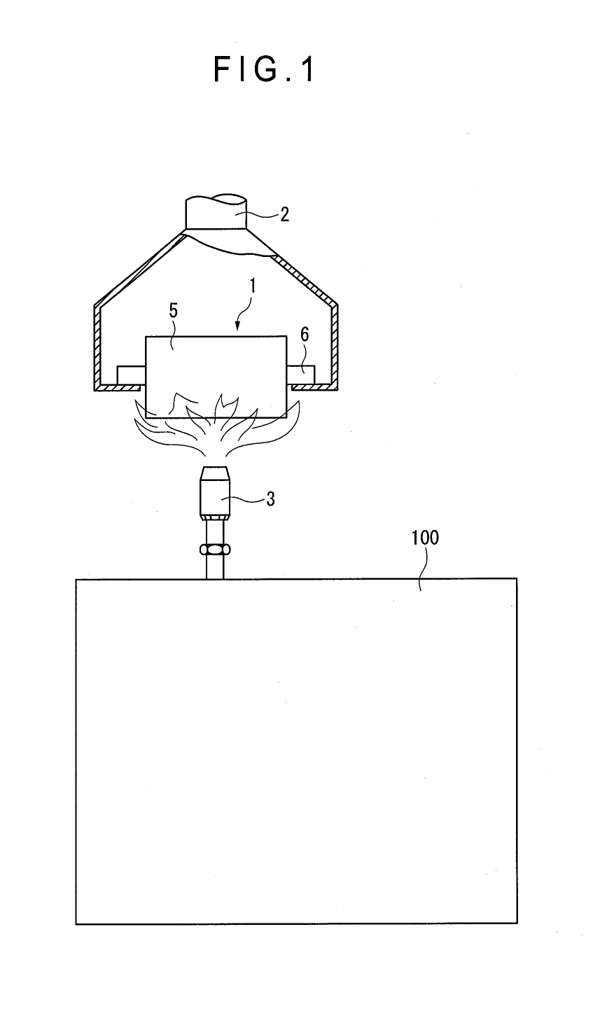

FIG. 1 shows an example in which a thermoelectric generator 1 according to the exemplary embodiment is provided at a burner-combustion portion in a heat-treating furnace 100. In order to exhaust a used gas from the heat-treating furnace 100, the gas is combusted as a fuel by a gas burner 3 and the combustion exhaust gas is discharged through an exhaust duct 2. The gas burner 3 for combustion is located below the exhaust duct 2 and the thermoelectric generator 1 is located at a position to which flame from the gas burner 3 reaches. When being exposed to flame from the gas burner 3, the thermoelectric generator 1 converts a thermal energy resulting from the gas combustion into electricity.

Incidentally, the thermoelectric generator according to the exemplary embodiment is exemplarily provided in the heat-treating furnace 100 and may be provided anywhere exposed to a high temperature.

### Description of Overall Arrangement of Thermoelectric Generator

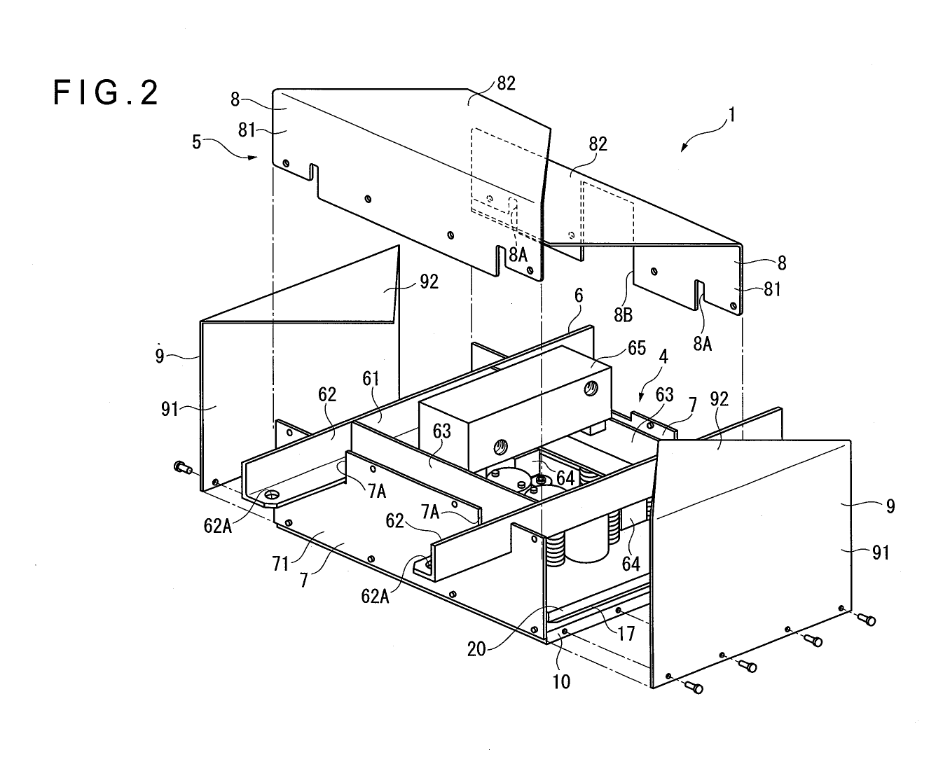

FIG. 2 is a perspective view of the thermoelectric generator 1. The thermoelectric generator 1 includes: a thermoelectric generation unit 4 that conducts thermoelectric conversion; a shielding cover 5 that covers the thermoelectric generation unit 4; and a fixing bracket 6 with which the thermoelectric generation unit 4 is fixed to the exhaust duct 2. The fixing bracket 6 is fixed to the exhaust duct 2.

### Brief Description of Thermoelectric Generation Unit

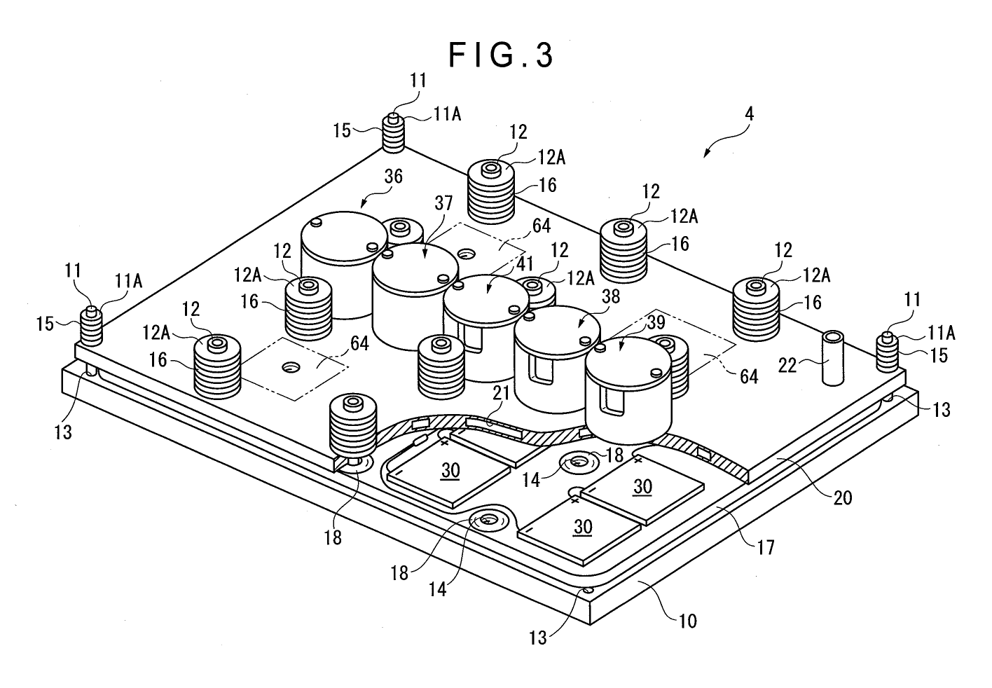

The thermoelectric generation unit 4, which will be described later in detail with reference to FIG. 3 and the subsequent figures, includes: a heat-receiving plate 10 located on the lower side in the figure; a cooling plate 20 located on the upper side; and a thermoelectric module interposed between the heat-receiving plate 10 and the cooling plate 20. When the cooling plate 20 is cooled with a cooling water while a lower surface of the heat-receiving plate 10 is heated with the flame of the gas burner 3 located therebelow, electricity is generated in the thermoelectric module interposed between the heat-receiving plate 10 and the cooling plate 20 by the Seebeck effect resulting from a temperature difference between the heat-receiving plate 10 and the cooling plate 20.

### Detailed Description of Shielding Cover

The shielding cover 5 is used to protect the thermoelectric generation unit 4 from the flame of the gas burner 3 coming up from below. Specifically, the shielding cover 5 includes: a pair of long-side lower shields 7 and 7 bolted to long-side side surfaces of the heat-receiving plate 10 shaped in a rectangular plate in a plan view; long-side upper shields 8 and 8 bolted to upper edges of the long-side lower shields 7 and 7; and a pair of short-side shields 9 and 9 bolted to short-side side surfaces of the heat-receiving plate 10. The shields 7 to 9 are made of, for instance, stainless steel. An outline of the cooling plate 20 is slightly smaller than an outline of the heat-receiving plate 10, so that when the shielding cover 5 is attached to the heat-receiving plate 10, a gap is provided between the shielding cover 5 and the cooling plate 20.

The long-side lower shields 7 are substantially at the same level as the temporary-fixing bracket 6. In other words, the shields 7 and 8, which cover long sides of the thermoelectric generation unit 4, are vertically separable into two parts at the height of the fixing bracket 6. Accordingly, upper portions of the long-side lower shields 7 and lower portions of the long-side upper shields 8 are provided with slits 7A and 8A located at positions corresponding to the fixing bracket 6, respectively, thereby preventing the shields 7 and 8 from interfering with the fixing bracket 6 even when the shields 7 and 8 are thermally expanded. One of the long-side upper shields 8 is further provided with an opening 8B located between the slits 8A and 8A. An electric wiring from the thermoelectric generation unit 4 and a hose for cooling water are put through the opening 8B.

The shields 7, 8 and 9 have vertical side surfaces 71, 81 and 91, respectively. Vertical edges of the side surfaces 71 and 81 of the long-side lower and upper shields 7 and 8 and vertical edges of the side surfaces 91 of the short-side shields 9 adjacent to the long-side lower and upper shields 7 and 8 are abutted on one another, thereby covering all the sides of the thermoelectric generation unit 4. Further, upper portions of the long-side upper shields 8 and upper portions of the short-side shields 9 are provided with trapezoidal upper surfaces 82 and triangular upper surfaces 92 that are bent in a plane direction, respectively. Edges of the upper surfaces 82 and 92 are abutted on each other, thereby covering the entire area above the thermoelectric generation unit 4.

The side surfaces 71, 81 and 91 and the upper surfaces 82 and 92 of the shields 7 to 9 are not mutually bonded, so that the boundaries defined by the edges of the side surfaces 71, 81 and 91 and the edges of the upper surfaces 82 and 92 are displaceable to absorb differences in thermal expansion/contraction amount between the shields 7 to 9. Thus, the shielding cover 5 is unlikely to undergo thermal stress as a whole, so that even though the shields 7 and 9 are fixed to the thermoelectric generation unit 4, the thermoelectric generation unit 4, especially the heat-receiving plate 10, is unaffected by thermal stress. On the other hand, even when the heat-receiving plate 10 is thermally expanded/contracted, the boundaries between the shields 7 to 9 are displaceable depending on the thermal expansion/contraction, so that the shielding cover 5 is also unlikely to undergo stress and thus suppresses an influence of the flame from the gas burner 3 on the heat-receiving plate 10.

### Detailed Description of Fixing Bracket

The fixing bracket 6 includes a support frame 61 provided by joining metallic shape steels having an L-shaped cross section together substantially in the shape of a sharp sign (parallel cross). Specifically, the support frame 61 includes: a pair of parallel support frame members 62 each having both ends that protrude from the shielding cover 5; and a pair of parallel bridging frame members 63 that extend between the support frame members 62 within the shielding cover 5.

Both ends of the support frame members 62 are provided with bolt holes 62A. Bolts are inserted through the bolt holes 62A to fix the fixing bracket 6 to the exhaust duct 2.

A pair of metallic fixed blocks 64 are welded on a lower surface of each of the bridging frame members 63 at a longitudinal interval. The fixed blocks 64 are members for positioning the support frame 61 at a predetermined height relative to the cooling plate 20. The support frame 61 is fixed to an upper surface of the cooling plate 20 with bolts that penetrate through the bridging frame members 63 and the fixed blocks 64.

A metallic cooling water block 65 is provided on the bridging frame members 63. A supply hose for supplying a cooling water from the outside and a return hose for returning the cooling water to the outside are connected to the cooling water block 65 through the opening 8B of the long-side upper shield 8. Further, a supply hose for supplying the cooling water to an inflow port provided in the cooling plate 20 and a return hose for returning the cooling water from a discharge port provided in the cooling plate 20 are also connected to the cooling water block 65. In other words, the cooling water with an adjusted temperature is supplied from the outside to a cooling water circuit in the cooling plate 20 via the cooling water block 65 and returned to the outside from the cooling plate 20 via the cooling water block 65 after passing through the cooling water circuit.

### Detailed Description of Thermoelectric Generation Unit

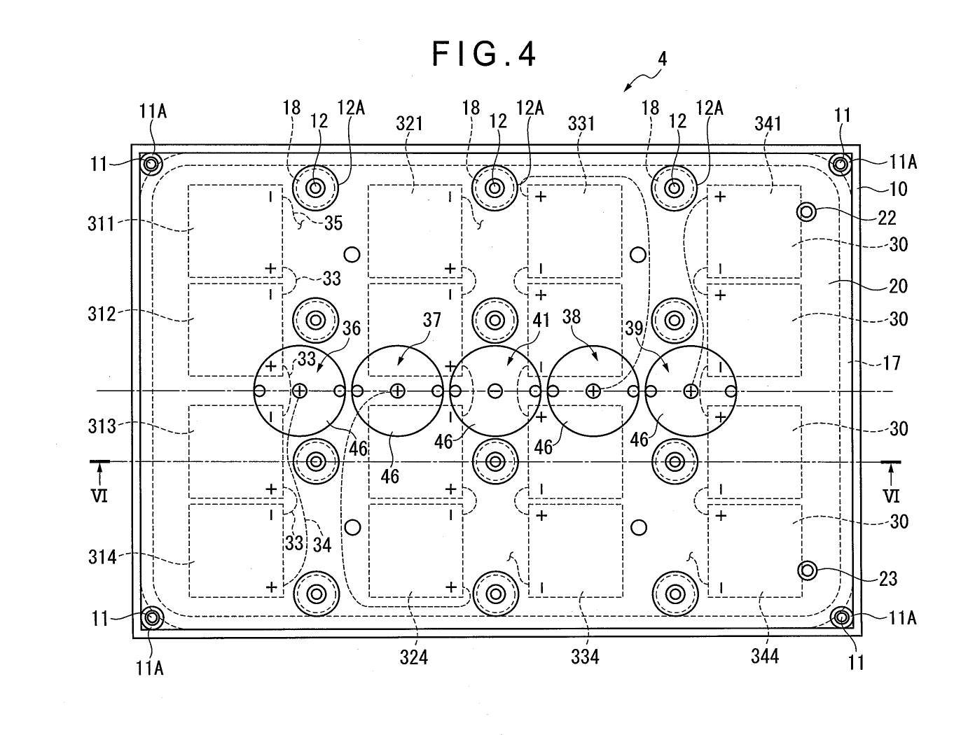

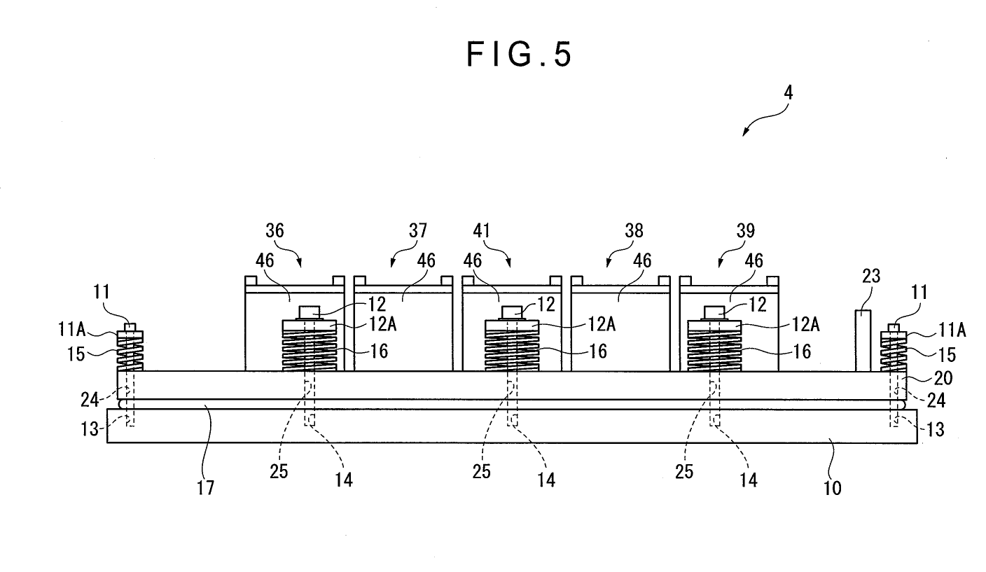

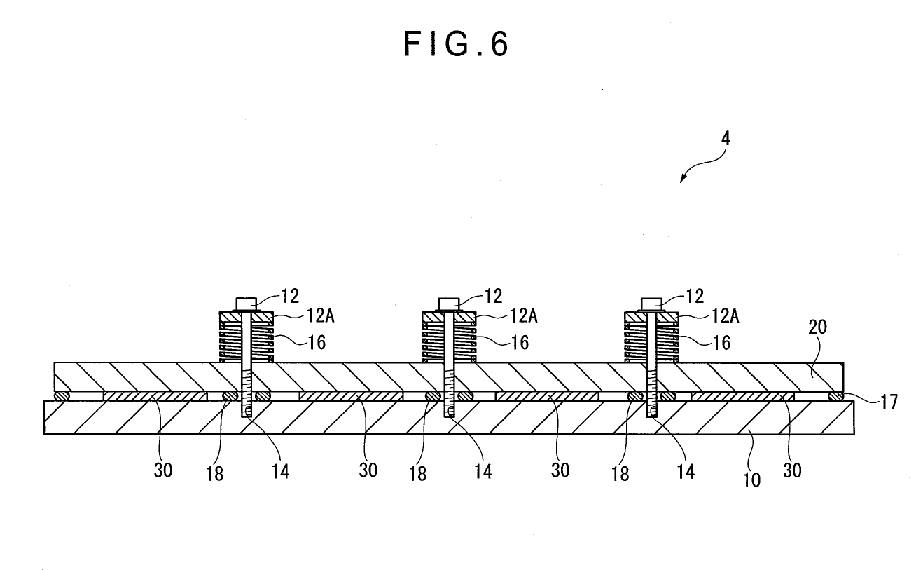

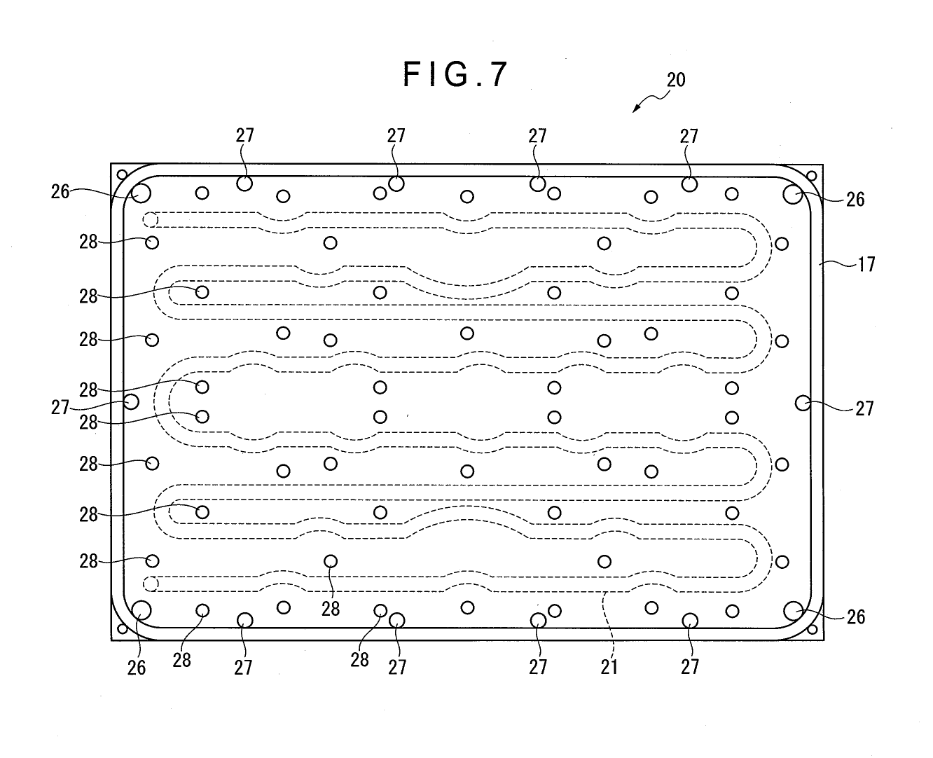

FIG. 3 is a perspective view showing the entirety of the thermoelectric generation unit 4. FIG. 4 is a plan view of the thermoelectric generation unit 4. FIG. 5 is a side view of the thermoelectric generation unit 4. FIG. 6 is a sectional view taken along a line VI-VI in FIG. 4. FIG. 7 is a back view of the cooling plate 20 of the thermoelectric generation unit 4.

As shown in FIGS. 3 to 5, the thermoelectric generation unit 4 includes: the heat-receiving plate 10 that is made of copper and in the shape of a rectangular plate and has an entire surface being surface-treated by black electroless nickel plating; the cooling plate 20 that is made of copper and in the shape of a rectangular plate having an outline slightly smaller than that of the heat-receiving plate 10; and a plurality of thermoelectric modules 30 that are interposed between the heat-receiving plate 10 and the cooling plate 20.

The heat-receiving plate 10 and the cooling plate 20 are fastened to each other with four bolts 11 arranged at the four corners and twelve bolts 12 arranged in four rows in parallel with the long sides and in three rows in parallel with the short sides. Accordingly, the heat-receiving plate 10 is provided with bolt holes 13 and 14 in which the bolts 11 and 12 are to be screwed and the cooling plate 20 is provided with insertion holes (described later) through which the bolts 11 and 12 are inserted.

### Functions of Coil Springs

Disc-shaped washers 11A are provided on the bolts 11 in a pierced manner. Coil springs 15 are also provided on the bolts 11 in a pierced manner to be interposed between the washers 11A and the upper surface of the cooling plate 20. Washers 12A are provided on the bolts 12 in a pierced manner Coil springs 16 are also provided on the bolts 12 in a pierced manner to be interposed between the washers 12A and the upper surface of the cooling plate 20. A wire diameter and an outside diameter of the coil springs 16 are larger than those of the coil springs 15 and a spring force of the coil springs 16 is larger than that of the coil springs 15. The respective spring forces of the coil springs 15 and 16 assist the heat-receiving plate 10 and the cooling plate 20 in a mutually approaching direction.

Further, a tetragonal O-ring 17 having four rounded corners is interposed between the heat-receiving plate 10 and the cooling plate 20 along respective peripheries of the heat-receiving plate 10 and cooling plate 20. The thermoelectric modules 30 are surrounded by the O-ring 17, so that the entry of water drop and steam from the outside is prevented to protect the thermoelectric modules 30 from the water drop and steam. The bolts 11 at the four corners are located at the outside of the O-ring 17 while being close to corners thereof. The other twelve bolts 12 are located at the inside of the O-ring 17.

The bolts 12 penetrate through the cooling plate 20 at the inside of the O-ring 17 and small annular O-rings 18 are arranged corresponding to the penetrated portions as shown in FIG. 6. All the O-rings 18 are arranged at the inside of the O-ring 17. The circumferences of the bolts 12 are sealed by the O-rings 18, thereby protecting the thermoelectric modules 30 from water drop and steam entering through the penetrated portions. A fluorocarbon rubber, which is excellent in heat resistance, is used as a material of the O-rings 17 and 18.

The coil springs 15 on the bolts 11 assist the respective four corners of the heat-receiving plate 10 and the cooling plate 20, which are easily separable due to thermal deformation, thereby reliably pressing down the corners of the O-ring 17 to favorably keep the O-ring 17 in close contact with the heat-receiving plate 10 and the cooling plate 20. In contrast, the coil springs 16 on the bolts 12 assist the heat-receiving plate 10 and the cooling plate 20, thereby reliably holding the thermoelectric modules 30 therebetween as well as keeping the heat-receiving plate 10 and the cooling plate 20 in close contact with linear portions of the O-ring 17 and with the O-rings 18. The coil springs 15 and 16 also serve to reliably suppress thermal warping of the heat-receiving plate 10 or the like.

### Arrangement of Cooling Plate

As shown in FIGS. 3 and 7, a cooling water circuit 21 through which a cooling water flows is provided within the cooling plate 20. The cooling plate 20 has a two-layered structure (not illustrated in detail). A plate material forming one of the layers is provided with a continuous winding groove that is substantially parallel with the long sides and is turned around near the short-side edges. This groove is covered by a plate material forming the other layer. In this manner, the cooling water circuit 21 is provided between the plate materials, i.e., within the cooling plate 20. The plate materials are brazed to each other at outer peripheries thereof into one piece.

On the upper surface of the cooling plate 20, an inflow port 22 stands upright at a position corresponding to one end of the cooling water circuit 21 and a discharge port 23 stands upright at a position corresponding to the other end of the cooling water circuit 21 (see FIGS. 4 and 5). The inflow port 22 and the discharge port 23 are connected to the supply hose and the return hose (not shown) from the cooling water block 65, respectively.

FIG. 7 shows a back surface of the cooling plate 20. As shown in FIG. 7, insertion holes 24 through which the above-mentioned bolts 11 are inserted are provided at the four corners of the cooling plate 20 and insertion holes 25 through which the bolts 12 are inserted are provided at twelve positions at an in-plane side of the cooling plate 20. Further, on the back surface of the cooling plate 20, positioning pins 26 stand upright adjacently to interior sides of the insertion holes 24 at the four corners, four positioning pins 27 stand upright along each of the long-side edges, and another positioning pin 27 stands upright at the intermediate position of each of the short-side edges. The O-ring 17 is provided to surround the positioning pins 26 and 27.

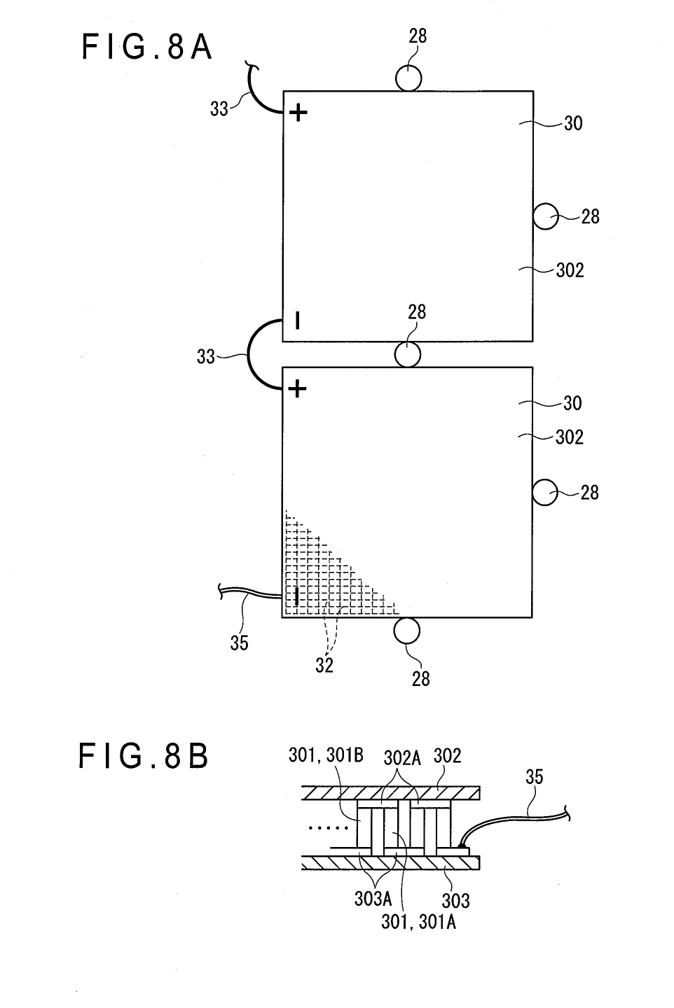

Further, on the back surface of the cooling plate 20, a number of positioning pins 28 for the thermoelectric modules 30 stand upright. As shown in FIG. 8A, the thermoelectric modules 30 are each substantially in the shape of a square plate in a plan view and three of the sides thereof are abutted on the positioning pins 28 to be positioned.

The positioning pins 26 to 28 are provided to the cooling plate 20 as described above because the cooling plate 20 hardly undergoes thermal expansion/contraction and thus the positioning of the O-rings 17 and 18 and the thermoelectric modules 30 can be favorably kept on the cooling plate 20.

Further, an outer peripheral end surface of the cooling plate 20 is provided with a band-shaped metal plate (not shown), by which a gap between the heat-receiving plate 10 and the cooling plate 20 is covered to reduce a thermal influence on the O-ring 17.

### Thermoelectric Modules

As shown in FIGS. 8A and 8B, the thermoelectric modules 30 each include plate-shaped heat-receiving planar portion 302 and cooling planar portion 303 and a plurality of thermoelectric elements 301 interposed therebetween. Specifically, the thermoelectric modules 30 each include: the heat-receiving planer portion 302; the cooling planer portion 303; heat-receiving-side electrodes 302A being arranged on an inner surface of the heat-receiving planar portion 302; cooling-side electrodes 303A being arranged on an inner surface of the cooling planar portion 303; and P-type thermoelectric elements 301A and N-type thermoelectric elements 301B having first end surfaces and second end surfaces, the first end surfaces being opposed to the heat-receiving planar portion 302 and connected to the heat-receiving-side electrodes 302A, the second end surfaces being opposed to the cooling planar portion 303 and connected to the cooling-side electrodes 303A. The P-type thermoelectric elements 301A and the N-type thermoelectric elements 301B are thus electrically connected to each other in series via the heat-receiving-side electrodes 302A and the cooling-side electrodes 303A in an alternate manner, thereby providing each of the thermoelectric modules 30.

Sixteen of the thus provided thermoelectric modules 30 in total are co-planarly arranged in four rows in parallel with the respective long sides of the heat-receiving plate 10 and the cooling plate 20 and in four rows in parallel with the respective short sides. Adjacent two of the four thermoelectric modules 30 arranged in parallel with the short sides are located close to each other (also see FIG. 4). The thermoelectric modules 30 are in contact with the heat-receiving plate 10 and the cooling plate 20 via a grease applied on front and back thereof. When the heat-receiving plate 10 is heated to a high temperature, the heat-receiving-side electrodes 37A of the thermoelectric modules 30 are thermally expanded. A temperature difference between the heat-receiving-side electrodes 37A and the cooling-side electrodes 38A causes warping of the thermoelectric modules 30.

Four of the thermoelectric modules 30 (311, 312, 313 and 314) arranged in parallel with the short sides and along the left edge in FIG. 4 are exemplarily described. As for an adjacent pair of thermoelectric modules 311 and 312 (313 and 314), a negative connection terminal of the thermoelectric module 311 (313) is electrically conductive with a positive connection terminal of the thermoelectric module 312 (314) via a lead wire 33. The same applies to the thermoelectric modules 312 and 313. As for the thermoelectric modules 311 and 314 located on both ends, a lead wire 34 is connected to a positive electrode of the thermoelectric module 314 while a lead wire 35 is connected to a negative electrode of the thermoelectric module 311. In other words, the thermoelectric modules 311 to 314 are electrically connected in series. The same applies to the other thermoelectric modules 30 arranged in fours in parallel with the short sides.

Consequently, as shown in FIG. 4, the lead wire 34 from the positive electrode of the thermoelectric module 314 located at the first column and the fourth row in FIG. 4 is connected to a first terminal block 36 (the leftmost one in FIG. 4) provided on the upper surface of the cooling plate 20, another lead wire 34 from a thermoelectric module 324 located at the second column and the fourth row is connected to a second terminal block 37, another lead wire 34 from a thermoelectric module 331 located at the third column and the first row is connected to a third terminal block 38, and another lead wire 34 from a thermoelectric module 341 located at the fourth column and the first row is connected to a fourth terminal block 39 (the rightmost one). In contrast, the lead wires 35 from respective negative electrodes of the thermoelectric module 311 located at the first column and the first row, a thermoelectric module 321 located at the second column and the first row, a thermoelectric module 334 located at the third column and the fourth row and a thermoelectric module 344 located at the fourth column and the fourth row are gathered into a bundle to be mutually electrically conductive and connected to a fifth terminal block 41 located at the center.

### Arrangement of Terminal Blocks

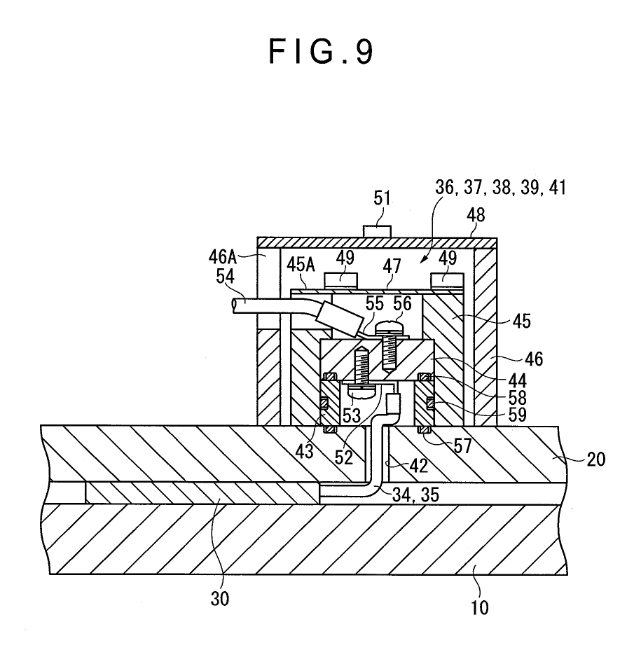

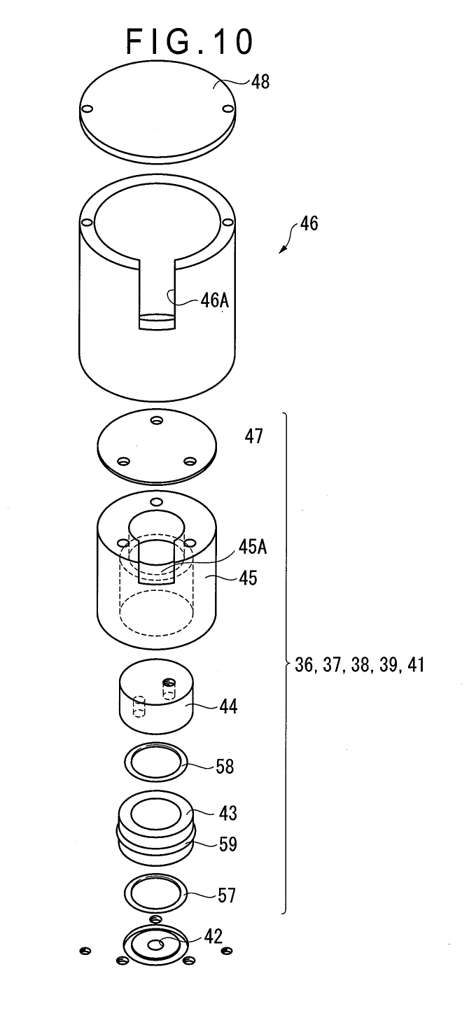

The first to fourth terminal blocks 36 to 39 and 41 will be described below with reference to FIGS. 9 and 10.

As shown in FIGS. 9 and 10, the first to fifth terminal blocks 36 to 39 and 41 are centralized on a center axis of the cooling plate 20 parallel with the long sides thereof with the fifth terminal block 41 being located at the center. The first to fifth terminal blocks 36 to 39 and 41 each include a spacer 43, a terminal 44 and a resin cover 45.

The cooling plate 20 is provided with through holes 42 located at positions corresponding to the first to fifth terminal blocks 36 to 39 and 41 and the lead wires 34 and 35 extending from the thermoelectric modules 30 are taken out through the through holes 42.

On the upper surface of the cooling plate 20, the cylindrical spacer 43 made of a fluoroplastic is provided to surround each of the through holes 42. The columnar terminal 44 made of an electrically conductive metal such as stainless steel is located on a top of the spacer 43. The spacer 43 and the terminal 44 are covered by the resin cover 45 made of a heat-resistant material such as a polyimide resin.

The first to fifth terminal blocks 36 to 39 and 41 are each covered by a metal cover 46 that is made of a material such as aluminum and directly fixed to the cooling plate 20. The resin cover 45 and the metal cover 46 are formed in a cylindrical shape and provided with cutout holes 45A and 46A made by cutting a part of the outer circumferences thereof from the upside, respectively. Upper openings of the covers 45 and 46 are closed by disc-shaped lids 47 and 48, respectively. The resin cover 45 and the lid 47 are fastened together and fixed to the cooling plate 20 with three bolts 49 while the metal cover 46 and the lid 48 are fastened together and fixed to the cooling plate 20 with two bolts 51.

A terminal 52 provided at an end of the lead wire 34 or 35 is fixed to a lower surface of the terminal 44 with a screw 53 and a terminal 55 of an external power line 54 is connected to an upper surface of the terminal 44 with a screw 56. The power line 54 is provided through the cutout holes 45A and 46A of the covers 45 and 46.

Further, an O-ring 57 is interposed between the upper surface of the cooling plate 20 and a lower surface of the spacer 43, an O-ring 58 is interposed between the spacer 43 and the terminal 44, and an O-ring 59 is interposed between the spacer 43 and the resin cover 45. The O-rings 57 to 59 serve to prevent water drop and steam that enters through gaps between the cooling plate 20 and the covers 45 and 46 and through the cut holes 45A and 46A of the covers 45 and 46 from entering an area where the thermoelectric modules 30 are arranged through the through hole 42 located inside the spacer 43.

Further, since the resin cover 45 and the O-rings 57 to 59 are covered by the metal cover 46, they are unaffected by an external heat, especially a radiant heat from the shielding cover 5. By preventing the O-rings 57 to 59 from deformation or the like as described above, airtightness can be favorably maintained.

Additionally, since the metal cover 46 is in contact with the upper surface of the cooling plate 20 to be cooled, the metal cover 46 is prevented from being excessively heated with a radiant heat from itself. Further, since the first to fifth terminal blocks 36 to 39 and 41 are centralized on the center axis of the cooling plate 20 in the vicinity of the center of the cooling plate 20 to be remoter from the shielding cover 5, the first to fifth terminal blocks 36 to 39 and 41 are less affected by the radiant heat from the shielding cover 5.

It should be appreciated that the scope of the invention is not limited to the above exemplary embodiment but modifications and improvements that are compatible with an object of the invention are included within the scope of the invention.

For instance, although the thermoelectric generator 1 is exemplarily provided in the heat-treating furnace 100 in the above exemplary embodiment, the thermoelectric generator according to the invention may be provided to anywhere having a heat source.

The cooling plate 20 is provided with the cooling water circuit 21 to be positively cooled with a cooling water in the above exemplary embodiment. However, since the cooling plate is merely required to be maintained at a low temperature as compared with the heat-receiving plate, such a positive cooling unit as the cooling water circuit may be omitted without departing from the scope of the invention.

Although the first to third O-rings 57 to 59 used in the first to fifth terminal blocks 36 to 39 and 41 are described in the exemplary embodiment, the second and third O-rings may be omitted depending on the structure of a terminal block. In other words, since the terminal block is attached on the cooling plate, an O-ring may be interposed at least between the cooling plate and a terminal irrespective of the structure of the terminal block.

### INDUSTRIAL APPLICABILITY

The invention is directed to a thermoelectric generator that generates electricity using heat from a heat source, which is usable in a variety of industrial equipments, engine-driven automobiles, construction machines, train cars, and the like.

### EXPLANATION OF CODE(S)

1 . . . thermoelectric generator, 4 . . . thermoelectric generation unit, 5 . . . shielding cover, 6 . . . fixing bracket, 10 . . . heat-receiving plate, 20 . . . cooling plate, 30 . . . thermoelectric module, 34, 35 . . . lead wires, 36 to 39, 41 . . . first to fifth terminal blocks, 42 . . . through hole, 43 . . . spacer, 44 . . . terminal, 45 . . . resin cover, 46 . . . metal cover, 54 . . . power line, 57 to 59 . . . first to third O-rings

1. A thermoelectric generator comprising:
a heat-receiving plate being adapted to receive heat;
a cooling plate being maintained at a low temperature as compared with the heat-receiving plate;
a thermoelectric module being interposed between the heat-receiving plate and the cooling plate;
a terminal block at which a lead wire from the thermoelectric module is connected to an external power line, the terminal block being located on the cooling plate; and
a metal cover being fixed on the cooling plate to cover the terminal block.

2. The thermoelectric generator according to claim 1, wherein
the cooling plate is provided with a through hole through which the lead wire is inserted,
the through hole is covered by the terminal block, and
an O-ring is interposed between the cooling plate and the terminal block to surround the through hole.

3. The thermoelectric generator according to claim 1, wherein the terminal block comprises a plurality of terminal blocks that are centralized in a vicinity of a center of the cooling plate.

4. The thermoelectric generator according to claim 3, further comprising:
a thermoelectric generation unit comprising the heat-receiving plate, the cooling plate and the thermoelectric module;
a metallic shielding cover being adapted to cover the thermoelectric generation unit; and
a fixing bracket being adapted to fix the thermoelectric generator at a predetermined position, wherein
the terminal blocks each comprise:
a resin spacer being located on the cooling plate;
a metallic terminal being located on the spacer to connect the lead wire and the power line to each other;
a resin cover being adapted to cover the spacer and the terminal;
a first O-ring being interposed between the cooling plate and the spacer;
a second O-ring being interposed between the spacer and the terminal; and
a third O-ring being interposed between the spacer and the resin cover.
